(19) United States
(12) Patent Application Publication
(10) Pub. No.: US 2026/0322337 A1
(43) Pub. Date: Oct. 15, 2026

(54) DIFFERENTIAL AMPLIFIER CIRCUIT

(71) Applicant: Murata Manufacturing Co., Ltd., Nagaokakyo-shi (JP)

(72) Inventors: Jun ENOMOTO, Nagaokakyo-shi (JP); Tomotaka MURATA, Nagaokakyo-shi (JP); Hideyuki SATO, Nagaokakyo-shi (JP)

(21) Appl. No.: 19/636,092

(22) Filed: Apr. 1, 2026

(30) Foreign Application Priority Data
Apr. 9, 2025 (JP) 2025-064115

(51) Int. Cl. H03F 1/56; H03F 3/45

(52) U.S. Cl. CPC H03F 1/56; H03F 3/45475; H03F 2200/222

(57) ABSTRACT

A first amplifier and a second amplifier amplify a differential signal. An input matching circuit includes a primary coil and a secondary coil that are inductively coupled with each other, with both end portions of the secondary coil being connected to respective input nodes of the first amplifier and the second amplifier. The input matching circuit outputs a high-frequency signal inputted to the primary coil from the secondary coil. A first bias circuit supplies a bias to each of the first amplifier and the second amplifier. A first bias interconnection connects the first bias circuit and the first amplifier and serves as a bias supply path. A second bias interconnection connects the first bias circuit and the second amplifier and serves as a bias supply path.

### CROSS REFERENCE TO RELATED APPLICATION

This application claims priority from Japanese Patent Application No. 2025-064115, filed on Apr. 9, 2025. The content of this application is incorporated herein by reference in its entirety.

### BACKGROUND OF THE DISCLOSURE

### 1. Field of the Disclosure

The present disclosure relates to a differential amplifier circuit.

### 2. Description of the Related Art

An amplifier circuit that converts a differential signal outputted from a differential amplifier into a single-ended signal using a balun is publicly known (Japanese Unexamined Patent Application Publication No. 2023-147645).

A primary coil and a secondary coil of the balun that converts a differential signal into a single-ended signal are inductively coupled, and there is a parasitic capacitance between them. The output node of the differential amplifier is connected to a load via the balun. When the load is seen from the differential amplifier, the output node of the differential amplifier is connected to the load via the parasitic capacitance of the balun as well. Because the transmission line through which a single-ended signal is transmitted is an unbalanced transmission line, a difference is caused in the load impedance when the load side is seen from a non-inverting signal amplifier and an inverting signal amplifier that constitute a differential pair. The difference in load impedance between the two amplifiers leads to a difference in gain and output power between the two amplifiers. If the symmetry between output signals is lost especially during high output, the overall output power of the amplifier circuit decreases.

The present disclosure aims to provide a differential amplifier circuit capable of mitigating a decrease in output even when a difference arises in load impedance between two amplifiers constituting a differential pair.

### BRIEF SUMMARY OF THE DISCLOSURE

According to an aspect of the present disclosure, provided is a differential amplifier circuit including: a first amplifier and a second amplifier configured to amplify a differential signal; an input matching circuit including a primary coil and a secondary coil that are inductively coupled with each other, the secondary coil being connected at a first end portion to an input node of the first amplifier and at a second end portion to an input node of the second amplifier, the input matching circuit being configured to output a high-frequency signal inputted to the primary coil from the secondary coil; a first bias circuit configured to supply a bias to each of the first amplifier and the second amplifier; a first bias interconnection connecting the first bias circuit and the first amplifier and serving as a bias supply path; a second bias interconnection connecting the first bias circuit and the second amplifier and serving as a bias supply path; and a substrate where the first amplifier, the second amplifier, the input matching circuit, the first bias circuit, the first bias interconnection, and the second bias interconnection are formed, in which the first bias circuit includes a first transistor and a second transistor connected in an emitter-follower configuration or in a source-follower configuration, with collectors or drains of the first transistor and the second transistor being connected to a bias power supply voltage, an emitter or a source of the first transistor being connected to the first amplifier via the first bias interconnection, and an emitter or a source of the second transistor being connected to the second amplifier via the second bias interconnection, the first amplifier and the second amplifier are arrayed in a first direction parallel to a surface of the substrate, with the first transistor and the second transistor being disposed within a region located on an opposite side of the second amplifier from the first amplifier in terms of the first direction, and the first bias interconnection includes a first middle portion extending in the first direction and disposed between the primary coil and a second amplifier connection portion of the second bias interconnection, the second amplifier connection portion being connected to the second amplifier, the first middle portion connecting the first transistor and a first amplifier connection portion of the first bias interconnection, the first amplifier connection portion being connected to the first amplifier.

According to another aspect of the present disclosure, provided is a differential amplifier circuit including: a first amplifier and a second amplifier configured to amplify a differential signal; an input matching circuit including a primary coil and a secondary coil that are inductively coupled with each other, the secondary coil being connected at a first end portion to an input node of the first amplifier and at a second end portion to an input node of the second amplifier, the input matching circuit being configured to output a high-frequency signal inputted to the primary coil from the secondary coil; a first bias circuit configured to supply a bias to the first amplifier; and a second bias circuit configured to supply a bias to the second amplifier, in which the first bias circuit is configured to adjust the bias in a direction in which a gain of the first amplifier increases upon an increase in power of a differential signal inputted to the first amplifier and the second amplifier, and the second bias circuit is configured to, upon an increase in power of the differential signal inputted to the first amplifier and the second amplifier, either not increase a gain of the second amplifier or adjust the bias in a direction in which the gain of the second amplifier increases under a condition that an amount of gain increase of the second amplifier is smaller than an amount of gain increase of the first amplifier.

The first middle portion of the first bias interconnection electromagnetically couples with the primary coil. Thus, a high-frequency signal is generated at the first bias interconnection by a high-frequency signal transmitted through the primary coil. Once this high-frequency signal is superimposed on the bias of the first amplifier to exhibit a self-bias effect, the gain of the first amplifier increases. Even if the first amplifier has a lower gain than the second amplifier due to a difference in load impedance between the first amplifier and the second amplifier, the gain of the first amplifier thus increases, which reduces the difference in gain. As a result, a decrease in output can be mitigated.

Further in a case where the first bias circuit is configured to adjust the bias in the direction in which the gain of the first amplifier increases, a difference in gain between the first amplifier and the second amplifier is also reduced. As a result, a decrease in output can be mitigated.

### BRIEF DESCRIPTION OF THE SEVERAL VIEWS OF THE DRAWINGS

FIG. 1 is an equivalent circuit diagram of a differential amplifier circuit according to a first embodiment;

FIG. 2 is a diagram showing the layout of a plurality of components of the differential amplifier circuit according to the first embodiment;

FIG. 3 is an equivalent circuit diagram of a first amplifier 21, a second amplifier 22, an input matching circuit 30, a first bias circuit 40, a first bias interconnection 51, and a second bias interconnection 52 of the differential amplifier circuit according to the first embodiment;

FIG. 4A is a graph showing simulation results of the time waveform of an emitter voltage of a first transistor 41;

FIG. 4B is a graph showing simulation results of the time waveform of an emitter voltage of a second transistor 42;

FIG. 4C is a graph showing an example of a relationship between output power and direct-current (DC) components of the emitter voltages of the first transistor 41 and the second transistor 42;

FIG. 4D is a graph showing an example of a relationship between output power and gains of the first amplifier 21 and the second amplifier 22;

FIG. 5 is an equivalent circuit diagram of the first amplifier 21, the second amplifier 22, the input matching circuit 30, the first bias circuit 40, the first bias interconnection 51, and the second bias interconnection 52 of the differential amplifier circuit according to the first embodiment;

FIG. 6 is a diagram showing the layout of a plurality of components of a differential amplifier circuit according to a modification of the first embodiment;

FIG. 7 is an equivalent circuit diagram of a differential amplifier circuit according to a second embodiment;

FIG. 8 is a diagram showing the layout of a plurality of components of the differential amplifier circuit according to the second embodiment;

FIG. 9A is an equivalent circuit diagram illustrating the operation of the differential amplifier circuit according to the second embodiment;

FIG. 9B is a graph showing an example of a relationship between output power and gains G₁ and G₂ of the first amplifier 21 and the second amplifier 22;

FIG. 10A is an equivalent circuit diagram illustrating the operation of the differential amplifier circuit according to the second embodiment;

FIG. 10B is a graph showing an example of a relationship between output power and the gains G₁ and G₂ of the first amplifier 21 and the second amplifier 22;

FIG. 11A is an equivalent circuit diagram illustrating the operation of the differential amplifier circuit according to the second embodiment;

FIG. 11B is a graph showing an example of a relationship between output power and the gains G₁ and G₂ of the first amplifier 21 and the second amplifier 22;

FIG. 12 is a schematic plan view showing the layout of a primary coil 31 of the input matching circuit 30, the first bias interconnection 51, and the second bias interconnection 52 of a differential amplifier circuit according to a third embodiment;

FIG. 13 is an equivalent circuit diagram of the first bias circuit 40 of a differential amplifier circuit according to a fourth embodiment;

FIG. 14 is an equivalent circuit diagram of a differential amplifier circuit according to a fifth embodiment;

FIG. 15 is a block diagram of a differential amplifier circuit according to a sixth embodiment;

FIG. 16 is a block diagram of a differential amplifier circuit according to a modification of the sixth embodiment;

FIG. 17 is a block diagram of a differential amplifier circuit according to another modification of the sixth embodiment;

FIG. 18 is a block diagram of a differential amplifier circuit according to further another modification of the sixth embodiment; and

FIG. 19 is a block diagram of a differential amplifier circuit according to further another modification of the sixth embodiment.

### DETAILED DESCRIPTION OF THE DISCLOSURE

### First Embodiment

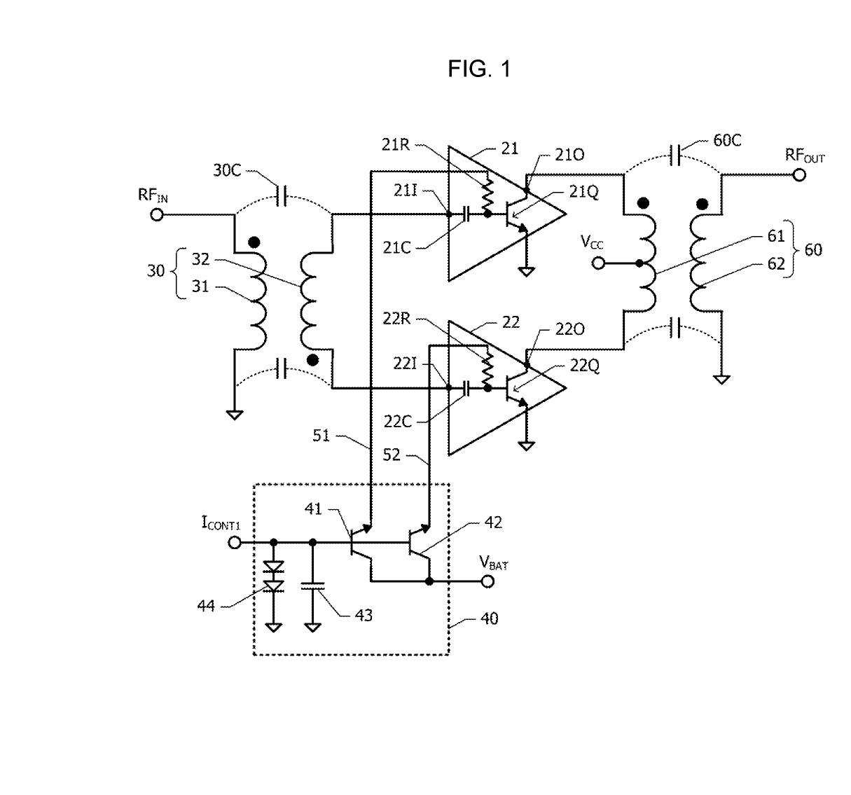

A differential amplifier circuit according to a first embodiment is described with reference to FIGS. 1 to 4D.

FIG. 1 is an equivalent circuit diagram of a differential amplifier circuit according to the first embodiment. The differential amplifier circuit according to the first embodiment includes a first amplifier 21 and a second amplifier 22 that amplify a differential signal, an input matching circuit 30, an output matching circuit 60, and a first bias circuit 40. In the present specification, a differential amplifier circuit refers to a circuit that amplifies signals by using two active elements as one pair and inputting signals having mutually opposite phases to the respective active elements and may also be referred to as an amplifier circuit having a push-pull configuration.

The input matching circuit 30 includes a primary coil 31 and a secondary coil 32 inductively coupled with each other. The secondary coil 32 is connected at one end portion to an input node 21I of the first amplifier 21 and at the other end portion to an input node 22I of the second amplifier 22. A high-frequency signal RF_{IN} is inputted to one end portion of the primary coil 31, and the other end portion thereof is connected to a reference potential (a ground potential). The input matching circuit 30 converts the high-frequency signal RF_{IN} inputted to the primary coil 31 into a differential signal and outputs the differential signal from the secondary coil 32. Thus, the input matching circuit 30 is a balun that converts a single-ended signal to a differential signal.

The input matching circuit 30 has a polarity that induces a voltage directed so that the potential at the end portion of the secondary coil 32 on the second amplifier 22 side is higher than the potential at the end portion of the secondary coil 32 on the first amplifier 21 side in a period in which the voltage of the high-frequency signal RF_{IN} is positive.

The first amplifier 21 includes an amplification transistor 21Q, a ballast resistance element 21R, and an input capacitor 21C. For example, the first amplifier 21 is formed by a plurality of cells connected in parallel, each cell including the amplification transistor 21Q, the ballast resistance element 21R, and the input capacitor 21C. Similarly, the second amplifier 22 includes amplification transistors 22Q, ballast resistance elements 22R, and input capacitors 22C. For example, heterojunction bipolar transistors (HBT) are used as the amplification transistors 21Q and 22Q.

The secondary coil 32 of the input matching circuit 30 is connected at one end portion to the base of the amplification transistor 21Q via the input capacitor 21C and at the other end portion to the base of the amplification transistor 22Q via the input capacitor 22C.

The first bias circuit 40 supplies a bias current to each of the first amplifier 21 and the second amplifier 22. For example, the first bias circuit 40 supplies a bias current to the base of the amplification transistor 21Q of the first amplifier 21 via the ballast resistance element 21R and supplies a bias current to the base of the amplification transistor 22Q of the second amplifier 22 via the ballast resistance element 22R.

A first bias interconnection 51 connects the first bias circuit 40 and the first amplifier 21 and serves as a bias supply path to the first amplifier 21. A second bias interconnection 52 connects the first bias circuit 40 and the second amplifier 22 and serves as a bias supply path to the second amplifier 22.

The first bias circuit 40 includes a first transistor 41, a second transistor 42, a capacitor 43, and a diode circuit 44. HBTs are used as the first transistor 41 and the second transistor 42. The first transistor 41 and the second transistor 42 are connected in an emitter-follower configuration. Thus, the collectors of the first transistor 41 and the second transistor 42 are connected to a bias power supply voltage V_{BAT}, the emitter of the first transistor 41 is connected to the first amplifier 21 via the first bias interconnection 51, and the emitter of the second transistor 42 is connected to the second amplifier 22 via the second bias interconnection 52.

A bias control current I_{CONT1} is supplied to the bases of the first transistor 41 and the second transistor 42. The bases of the first transistor 41 and the second transistor 42 are connected to the reference potential via the capacitor 43 and are connected to the reference potential via the diode circuit 44 as well. For example, the diode circuit 44 includes diodes in a two-stage configuration connected in the forward direction from the bases of the first transistor 41 and the second transistor 42 toward the reference potential. Base voltages of the first transistor 41 and the second transistor 42 are fixed to the forward voltage of the diode circuit 44.

The output matching circuit 60 includes a primary coil 61 and a secondary coil 62 that are inductively coupled with each other. The primary coil 61 is connected at one end portion to an output node 21O of the first amplifier 21 and at the other end portion to an output node 22O of the second amplifier 22. A midpoint on the primary coil 61 is connected to a power supply voltage V_{CC}. The power supply voltage V_{CC} is supplied to the collectors of the amplification transistor 21Q of the first amplifier 21 and the amplification transistor 22Q of the second amplifier 22 via the primary coil 61.

The secondary coil 62 of the output matching circuit 60 is connected to the reference potential at one end portion and outputs an amplified high-frequency signal RF_{OUT} from the other end portion. The high-frequency signal RF_{OUT} is a single-ended signal.

A parasitic capacitance 30C is generated between the primary coil 31 and the secondary coil 32 of the input matching circuit 30, and also, a parasitic capacitance 60C is generated between the primary coil 61 and the secondary coil 62 of the output matching circuit 60. The input node 21I of the first amplifier 21 and the input node 22I of the second amplifier 22 are connected to a signal source not only via the input matching circuit 30 but also via the parasitic capacitance 30C. As a result, signal source impedance as seen from the first amplifier 21 and the second amplifier 22 is different between the first amplifier 21 and the second amplifier 22. Similarly, the output node 21O of the first amplifier 21 and the output node 21O of the second amplifier 22 are connected to the load through the parasitic capacitance 60C, and as a result, the load impedance as seen from the first amplifier 21 and the second amplifier 22 is different between the first amplifier 21 and the second amplifier 22.

When the signal source impedance and the load impedance are different between the first amplifier 21 and the second amplifier 22, a difference in gain arises between the first amplifier 21 and the second amplifier 22. Loss of symmetry between output signals especially during high output leads to degradation in the amplification characteristics of the entire differential amplifier circuit, such as a decrease in output power. The first embodiment mitigates degradation of the amplification characteristics attributable to the asymmetry of output signals between the first amplifier 21 and the second amplifier 22. The following describes a configuration for enabling mitigation of degradation of amplification characteristics.

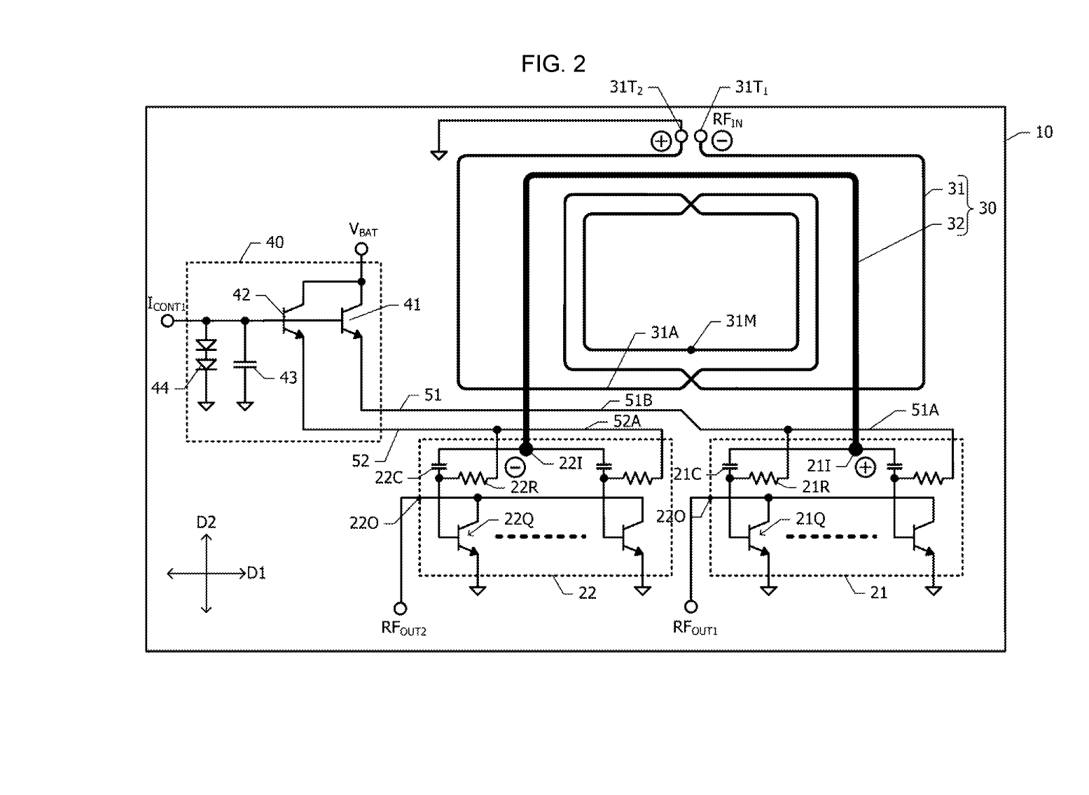

FIG. 2 is a diagram showing the layout of a plurality of components of the differential amplifier circuit according to the first embodiment. The first amplifier 21, the second amplifier 22, the input matching circuit 30, the first bias circuit 40, the first bias interconnection 51, and the second bias interconnection 52 are formed on a semiconductor substrate 10. The first amplifier 21 is formed by a plurality of cells each including the amplification transistor 21Q, the input capacitor 21C, and the ballast resistance element 21R. The second amplifier 22 is formed by a plurality of cells each including the amplification transistor 22Q, the input capacitor 22C, and the ballast resistance element 22R.

The plurality of amplification transistors 21Q and the plurality of amplification transistors 22Q are arrayed in one direction parallel to the surface of the semiconductor substrate 10. The direction in which the plurality of amplification transistors 21Q and the plurality of amplification transistors 22Q are arrayed is referred to as a first direction D1 (the horizontal direction in FIG. 2). The direction orthogonal to the first direction D1 in the surface of the semiconductor substrate 10 is referred to as a second direction D2 (the vertical direction in FIG. 2). The plurality of input capacitors 21C and the plurality of ballast resistance elements 21R of the first amplifier 21 as well as the plurality of input capacitors 22C and the plurality of ballast resistance elements 22R of the second amplifier 22 are also arrayed in the first direction D1.

The first amplifier 21 and the second amplifier 22 are arrayed in the first direction D1. The first transistor 41 and the second transistor 42 of the first bias circuit 40 are disposed within a region at an opposite side of the second amplifier 22 from the first amplifier 21 in terms of the first direction D1. The capacitor 43 and the diode circuit 44 of the first bias circuit 40 are also disposed within a region at an opposite side of the second amplifier 22 from the first amplifier 21 in terms of the first direction D1. Note that there are no particular limitations as to the relationship between the position of the first bias circuit 40 in terms of the second direction D2 and the positions of the first and second amplifiers 21 and 22 in terms of the second direction D2. In the example shown in FIG. 2, the first transistor 41 and the second transistor 42 of the first bias circuit 40 are disposed at positions shifted from the first amplifier 21 and the second amplifier 22 in the second direction D2.

The input matching circuit 30 is disposed at a position shifted from the first amplifier 21 and the second amplifier 22 in the second direction D2. The first amplifier 21 and the second amplifier 22 are disposed on the respective sides of a straight line parallel to the second direction D2 and passing through the geometric center of the input matching circuit 30. The number of turns of the primary coil 31 is, for example, approximately three, and end portions 31T₁ and 31T₂ of the primary coil 31 are disposed at positions farthest from the first amplifier 21 and the second amplifier 22 in terms of the second direction D2. Specifically, a winding portion of the primary coil 31 is disposed between the end portions 31T₁ and 31T₂ of the primary coil 31 and the first and second amplifiers 21 and 22 in terms of the second direction D2.

The number of turns of the secondary coil 32 is, for example, slightly less than one. The secondary coil 32 is connected at one end portion to the plurality of input capacitors 21C of the first amplifier 21 and at the other end portion to the plurality of input capacitors 22C of the second amplifier 22.

The first bias interconnection 51 is connected to the plurality of ballast resistance elements 21R of the first amplifier 21. Because the plurality of ballast resistance elements 21R are arrayed in the first direction D1, the first bias interconnection 51 is connected to the first amplifier 21 in a certain region long in the first direction D1. A portion of the first bias interconnection 51 connected to the first amplifier 21 is referred to as a first amplifier connection portion 51A. Similarly, the second bias interconnection 52 is connected to the second amplifier 22 at a second amplifier connection portion 52A long in the first direction D1.

The high-frequency signal RF_{IN} is inputted to the one end portion 31T₁ of the primary coil 31, and the other end portion 31T₂ is connected to the reference potential. In a period in which the voltage of the high-frequency signal RF_{IN} is deflected in the negative direction with respect to the reference potential, a voltage that is negative with respect to the end portion of the secondary coil 32 connected to the first amplifier 21 is generated at the end portion of the secondary coil 32 connected to the second amplifier 22. Under the assumption that a midpoint on the secondary coil 32 is a virtual reference potential, a negative voltage is applied to the second amplifier 22, and a positive voltage is applied to the first amplifier 21. FIG. 2 shows this relationship of positive and negative polarities using circled plus and minus signs. Note that the end portion 31T₂ connected to the reference potential is denoted with a plus sign because a potential that is positive with respect to the other end portion 31T₁ is generated at the end portion 31T₂.

The first bias interconnection 51 includes a first middle portion 51B disposed between the primary coil 31 and the second amplifier connection portion 52A of the second bias interconnection 52 and extending in the first direction D1. The first middle portion 51B connects the first transistor 41 and the first amplifier connection portion 51A of the first bias interconnection 51. The shortest distance between the primary coil 31 and the first middle portion 51B of the first bias interconnection 51 is smaller than the shortest distance between the primary coil 31 and the second amplifier connection portion 52A of the second bias interconnection. Thus, the first middle portion 51B of the first bias interconnection 51 strongly couples with the primary coil 31 electromagnetically (capacitive coupling and inductive coupling). The electromagnetic coupling between the first middle portion 51B and the primary coil 31 is stronger than the electromagnetic coupling between the primary coil 31 and the second amplifier connection portion 52A of the second bias interconnection 52.

The primary coil 31 includes a first coupling portion 31A disposed at a distance from the first middle portion 51B of the first bias interconnection 51 in the second direction D2 and extending in the first direction D1. No other portion of the primary coil 31 is disposed between the first coupling portion 31A and the first middle portion 51B. The first coupling portion 31A is located in between the end portion 31T₂, which is one of the end portions of the primary coil 31, and a midpoint 31M on the primary coil 31, the end portion 31T₂ being the end portion where the same polarity as the polarity exhibited at the end portion of the secondary coil 32 connected to the first amplifier 21 is exhibited.

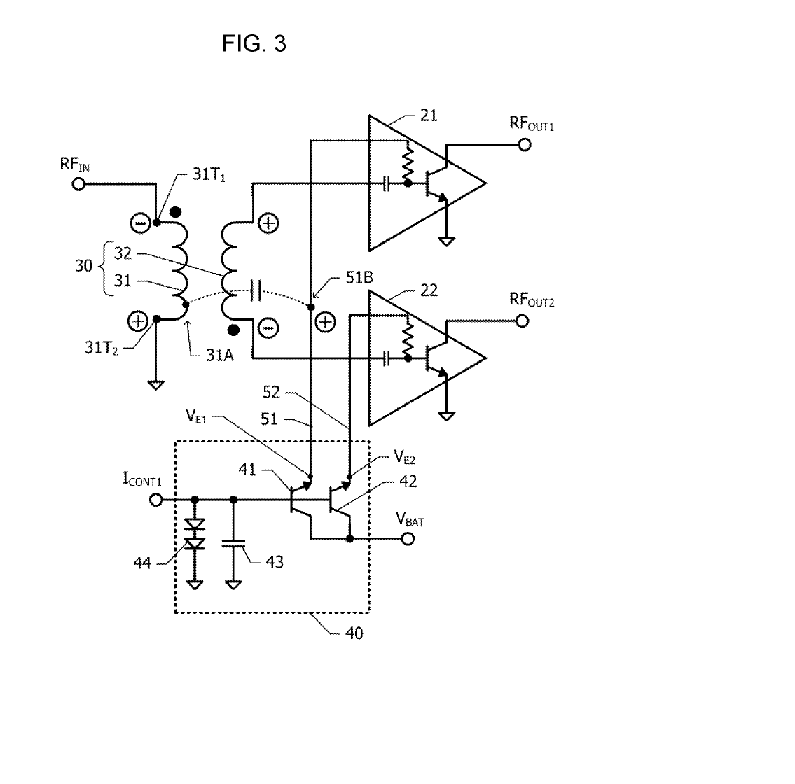

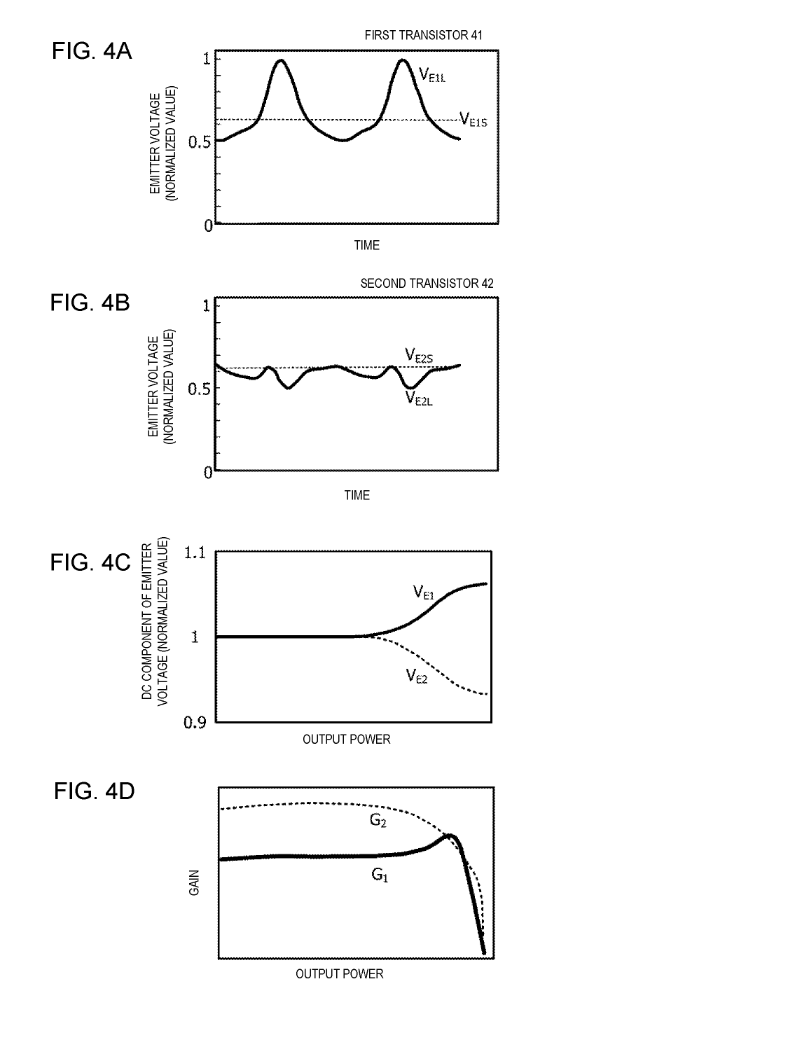

Next, with reference to FIGS. 3 to 4D, a description is given of the operation, focusing on the capacitive coupling between the first coupling portion 31A of the primary coil 31 and the first middle portion 51B of the first bias interconnection 51. FIG. 3 is an equivalent circuit diagram of the first amplifier 21, the second amplifier 22, the input matching circuit 30, the first bias circuit 40, the first bias interconnection 51, and the second bias interconnection 52 of the differential amplifier circuit according to the first embodiment.

The first coupling portion 31A of the primary coil 31 and the first middle portion 51B of the first bias interconnection 51 are capacitively coupled. When the voltage at the one end portion 31T₂ of the primary coil 31 is deflected to a relatively positive side, a relatively positive voltage is applied to the first amplifier 21, and a relatively negative voltage is inputted to the second amplifier 22. A relatively positive voltage is generated at the first middle portion 51B of the first bias interconnection 51 due to the capacitive coupling with the first coupling portion 31A of the primary coil 31. Conversely, when the voltage at the one end portion 31T₂ of the primary coil 31 is deflected to a relatively negative side, a relatively negative voltage is generated at the first middle portion 51B of the first bias interconnection 51.

Because the voltage of the first middle portion 51B is deflected in the positive direction and in the negative direction, a high-frequency signal is generated at the emitter of the first transistor 41 of the first bias circuit 40. Because this high-frequency signal is in phase with the high-frequency signal inputted from the secondary coil 32 to the first amplifier 21, a voltage having the high-frequency signal generated at the first middle portion 51B of the first bias interconnection 51 superimposed on the high-frequency signal inputted to the first amplifier 21 is generated at the emitter of the first transistor 41. As a result, the high-frequency signal generated at the emitter of the first transistor 41 has a large amplitude.

The second bias interconnection 52, on the other hand, exhibits almost no electromagnetic coupling with the primary coil 31, and thus, the high-frequency signal generated at the emitter of the second transistor 42 has an amplitude smaller than an amplitude of the high-frequency signal generated at the emitter of the first transistor 41.

FIG. 4A is a graph showing simulation results of the time waveform of an emitter voltage of the first transistor 41. The solid line represents an emitter voltage V_{E1L} when the output power is large, and the broken line represents an emitter voltage V_{E1S} when the output power is small. Whether the output power is large or small corresponds to whether the amplitude of the high-frequency signal RF_{IN} inputted to the input matching circuit 30 is large or small. In the graph shown in FIG. 4A, the horizontal axis represents time, and the vertical axis represents the normalized value of voltage. The normalized value of voltage is a voltage normalized based on the maximum value of the emitter voltage V_{E1L} of the first transistor 41.

When the output power is small, that is, when the amplitude of the high-frequency signal inputted to the first amplifier 21 is small, the emitter voltage V_{E1S} of the first transistor 41 is determined based on the base voltage of the first transistor 41 and is almost constant.

When the output power is large, the emitter voltage V_{E1L} of the first transistor 41 is affected not only by the high-frequency signal inputted to the first amplifier 21, but also by the capacitive coupling between the first coupling portion 31A of the primary coil 31 and the first middle portion 51B of the first bias interconnection 51. Affected by them, the emitter voltage V_{E1L} of the first transistor 41 has a larger amplitude. In this event, the emitter voltage V_{E1L} of the first transistor 41 does not become a value obtained by subtracting the forward voltage between the base and the emitter from the base voltage of the first transistor 41 or below. Thus, the amount of decrease of the emitter voltage V_{E1L} in the period in which the high-frequency signal inputted to the first amplifier 21 is deflected in the negative direction is restricted by the base voltage of the first transistor 41.

For the reasons above, the time waveform of the emitter voltage V_{E1L} when the input power is large is shaped such that the positive deflected amplitude is larger than the negative deflected amplitude by reference to the emitter voltage V_{E1S} when the input power is small. Thus, the average value of the emitter voltage V_{E1L} is larger than the average value of the emitter voltage V_{E1S} when the input power is small.

In the period in which the emitter voltage V_{E1L} is deflected in the positive direction, the emitter current of the first transistor 41 (FIG. 3) decreases. In the period in which the emitter voltage V_{E1L} is deflected in the negative direction, the emitter current of the first transistor 41 increases. When time-averaged, the average value of the emitter current of the first transistor 41 when the output power is large is larger than the average value of the emitter current of the first transistor 41 when the output power is small. This corresponds to an increase in the bias current supplied to the amplification transistor 21Q of the first amplifier 21 (FIG. 1). The effect where the bias current of the amplification transistor 21Q increases with an increase in the power of the high-frequency signal inputted to the first amplifier 21 is referred to as a self-bias effect.

FIG. 4B is a graph showing simulation results of the time waveform of the emitter voltage of the second transistor 42 (FIG. 3). The solid line represents an emitter voltage V_{E2L} when the output power is large, and the broken line represents an emitter voltage V_{E2S} when the output power is small. The horizontal axis represents time, and the vertical axis represents the normalized value of voltage. The normalized value of voltage is a voltage normalized based on the maximum value of the emitter voltage V_{E1L} of the first transistor 41 shown in FIG. 4A.

When the output power is small, the emitter voltage V_{E2S} of the second transistor 42 is almost equal to the emitter voltage V_{E1S} of the first transistor 41. When the output power is large, the emitter voltage V_{E2L} of the second transistor 42 fluctuates according to the waveform of the high-frequency signal, but its amplitude is smaller than that of the emitter voltage V_{E1L} of the first transistor 41 because the second bias interconnection 52 (FIG. 3) connected to the emitter of the second transistor 42 exhibits almost no electromagnetic coupling with the primary coil 31. For this reason, the self-bias effect is not exhibited.

FIG. 4C is a graph showing an example of a relationship between the output power and direct-current (DC) components of the emitter voltages of the first transistor 41 and the second transistor 42. The horizontal axis represents the output power from the differential amplifier circuit, and the vertical axis represents DC components of the emitter voltages of the first transistor 41 and the second transistor 42, expressed in values normalized based on the emitter voltage when the output power is sufficiently small. The solid line and the broken line in FIG. 4C represent a DC component of an emitter voltage V_{E1} of the first transistor 41 and a DC component of an emitter voltage V_{E2} of the second transistor 42, respectively.

In a range where the output power is small, DC components of the emitter voltages of the first transistor 41 and the second transistor 42 are almost equal. When the output power is large, the emitter current of the first transistor 41 increases as described with reference to FIG. 4A. As a result, the emitter current of the second transistor 42 decreases relatively. Consequently, the emitter voltage V_{E2} of the second transistor 42 decreases.

FIG. 4D is a graph showing an example of a relationship between the output power and the gains of the first amplifier 21 and the second amplifier 22. The horizontal axis represents the output power from the differential amplifier circuit, and the vertical axis represents gain. The solid line and the broken line in FIG. 4D represent a gain G₁ of the first amplifier 21 and a gain G₂ of the second amplifier 22, respectively. FIG. 4D shows an example in which when the output power is small, the gain G₂ of the second amplifier 22 is higher than the gain G₁ of the first amplifier 21. Such a difference in gain arises because there are differences in signal source impedance and load impedance between the first amplifier 21 and the second amplifier 22 due to the parasitic capacitances 30C and 60C of the input matching circuit 30 and the output matching circuit 60 shown in FIG. 1.

When the output power rises, the gain G₁ of the first amplifier 21 increases because the DC component of the emitter voltage V_{E1} of the first transistor 41 increases. An effect where the gain increases as the output power rises is referred to as gain expansion. When the DC component of the emitter voltage V_{E2} of the second transistor 42 decreases with a rise in the output power, the gain G₂ of the second amplifier 22 decreases as well. As a result of an increase in the gain G₁ of the first amplifier 21 and a decrease in the gain G₂ of the second amplifier 22, their magnitudes become almost equal at a particular output power. The asymmetry in gain when the output power rises can thus be mitigated.

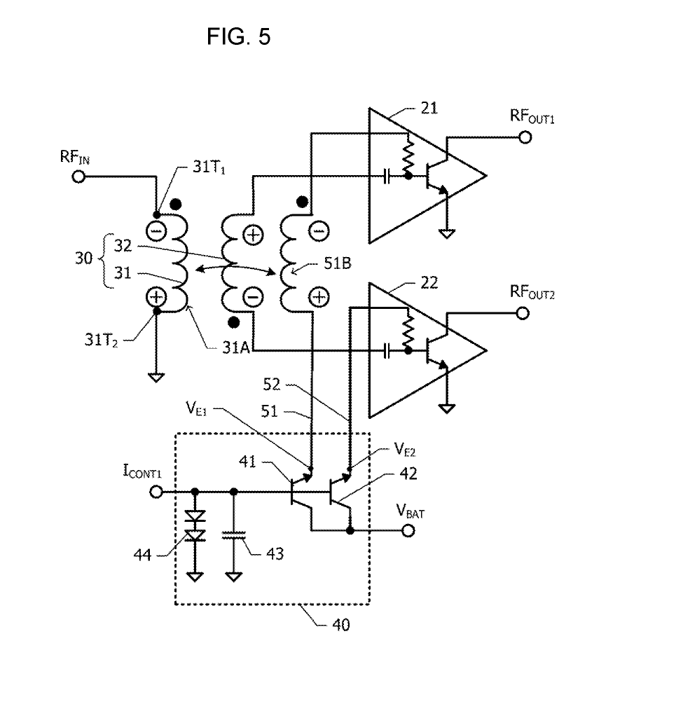

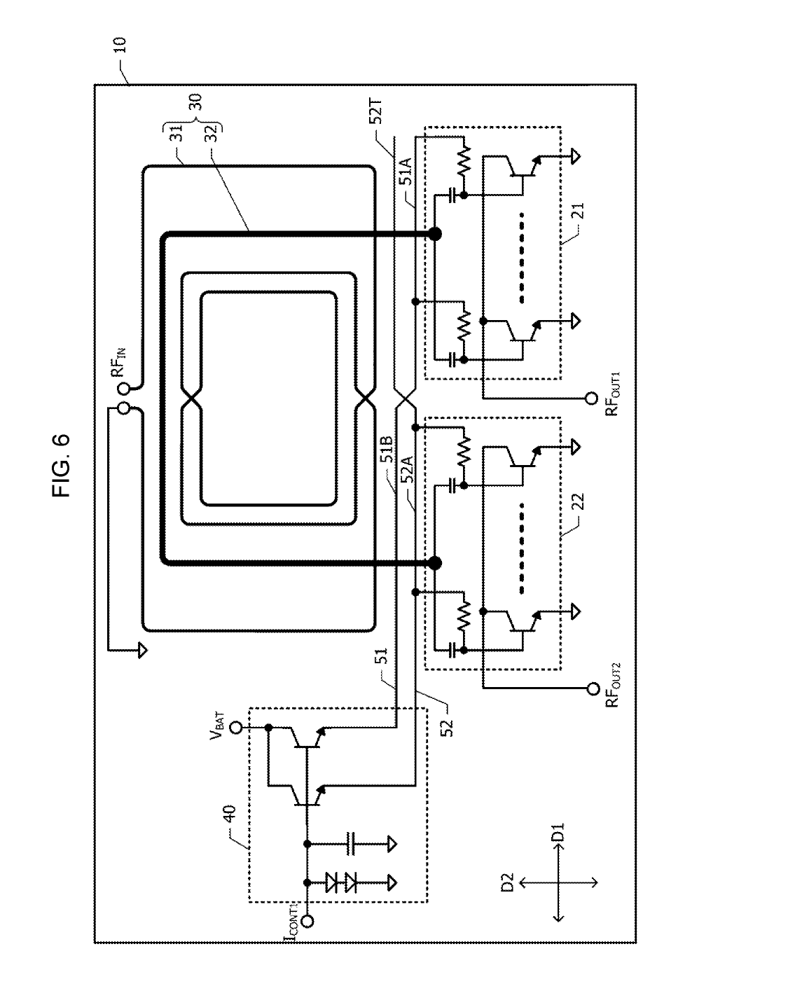

Next, the operation is described with reference to FIG. 5, focusing on the inductive coupling between the first coupling portion 31A of the primary coil 31 and the first middle portion 51B of the first bias interconnection 51. FIG. 5 is an equivalent circuit diagram of the first amplifier 21, the second amplifier 22, the input matching circuit 30, the first bias circuit 40, the first bias interconnection 51, and the second bias interconnection 52 of the differential amplifier circuit according to the first embodiment.

The first coupling portion 31A of the primary coil 31 of the input matching circuit 30 and the first middle portion 51B of the first bias interconnection 51 are inductively coupled. When a voltage directed from the one end portion 31T₁ to the other end portion 31T₂ of the primary coil 31 is generated, an inductive voltage is generated at the secondary coil 32, and directed from the end portion connected to the second amplifier 22 to the end portion connected to the first amplifier 21. Also, an inductive voltage is generated at the first middle portion 51B of the first bias interconnection 51, and directed from the first amplifier 21 to the emitter of the first transistor 41.

When the voltage of the high-frequency signal inputted to the first amplifier 21 is deflected in the positive direction, the deflected amplitude of the voltage generated at the emitter of the first transistor 41 is increased because the inductive voltage generated at the first middle portion 51B is superimposed thereon. Thus, a voltage waveform similar to the emitter voltage V_{E1L} shown in FIG. 4A is generated. As a result, the asymmetry in gain caused by a rise in the output power can be mitigated.

As described above, the asymmetry in gain caused by a rise in the output power can be mitigated in both a case where the primary coil 31 of the input matching circuit 30 and the first middle portion 51B of the first bias interconnection 51 are thought to be capacitively coupled and a case where they are thought to be inductively coupled.

Note that in a case where the primary coil 31 of the input matching circuit 30 and the first middle portion 51B of the first bias interconnection 51 are thought to be capacitively coupled, the first coupling portion 31A of the primary coil 31 (FIG. 2) needs to be located at a portion in between the midpoint 31M (FIG. 2) of the primary coil 31 and the one end portion 31T₂.

By contrast, in a case where the primary coil 31 of the input matching circuit 30 and the first middle portion 51B of the first bias interconnection 51 are thought to be inductively coupled, there is no limitation on a location on the primary coil 31 with which the first middle portion 51B of the first bias interconnection 51 is inductively coupled. The primary coil 31, the first bias interconnection 51, the first amplifier 21, and the second amplifier 22 may be arranged so that the direction of the inductive coupling between the first coupling portion 31A of the primary coil 31 (FIG. 5) and the first middle portion 51B may be as shown in FIG. 5. For example, they may be arranged so that the polarity exhibited at the end portion of the first middle portion 51B on the first amplifier 21 side is opposite to the polarity exhibited at the end portion of the secondary coil 32 connected to the first amplifier 21.

### Next, an effect of the first embodiment is described

According to the first embodiment, as shown in FIG. 4D, an effect of mitigating the asymmetry between the gain G₁ of the first amplifier 21 and the gain G₂ of the second amplifier 22 is obtained. As a result, the degradation in the amplification characteristics of the differential amplifier circuit is mitigated.

Next, a differential amplifier circuit according to a modification of the first embodiment is described with reference to FIG. 6. FIG. 6 is a diagram showing the layout of a plurality of components of the differential amplifier circuit according to the modification of the first embodiment. In the first embodiment (FIG. 2), the second bias interconnection 52 for the second amplifier 22 does not extend to a region where the first amplifier 21 is disposed, in terms of the first direction D1. By contrast, in the modification shown in FIG. 6, the second bias interconnection 52 extends in the first direction D1 to the region where the first amplifier 21 is disposed. The portion extending in the first direction D1 is referred to as a tip portion 52T of the second bias interconnection 52.

The tip portion 52T of the second bias interconnection 52 is disposed between the first amplifier connection portion 51A of the first bias interconnection 51 and the primary coil 31 of the input matching circuit 30 in terms of the second direction D2. Thus, the first bias interconnection 51 and the second bias interconnection 52 intersect between the first amplifier 21 and the second amplifier 22 in terms of the first direction D1.

The tip portion 52T of the second bias interconnection 52 electromagnetically couples with the primary coil 31 of the input matching circuit 30. Thus, a voltage waveform in accordance with the high-frequency signal propagating through the primary coil 31 is generated at the tip portion 52T. However, because the tip portion 52T is connected to the emitter of the second transistor 42 via the second amplifier connection portion 52A of the second bias interconnection 52, there is a low impact on the emitter voltage of the second transistor 42. Thus, even though the second bias interconnection 52 is extended in the first direction D1 to have the tip portion 52T, an effect of mitigating the asymmetry between the gain G₁ of the first amplifier 21 and the gain G₂ of the second amplifier 22 caused by a rise in the output power is obtained as in the first embodiment.

The provision of the tip portion 52T to the second bias interconnection 52 in the modification shown in FIG. 6 enables improvement in symmetry in shape and arrangement between the first bias interconnection 51 and the second bias interconnection 52.

Next, a differential amplifier circuit according to another modification of the first embodiment is described. Although HBTs are used in the first embodiment as the amplification transistor 21Q of the first amplifier 21, the amplification transistor 22Q of the second amplifier 22, and the first and second transistors 41 and 42 of the first bias circuit 40, MOSFETs may be used as these transistors. If MOSFETs are used, the emitters, collectors, and bases in the above descriptions are read as sources, drains, and gates, respectively, and the connection in an emitter-follower configuration is read as connection in a source-follower configuration.

Further, if MOSFETs are used, the bias current supplied to the first amplifier 21 and the second amplifier 22 is read as a bias voltage, and the bias control current I_{CONT1} supplied to the first bias circuit 40 is read as a bias control voltage.

### Second Embodiment

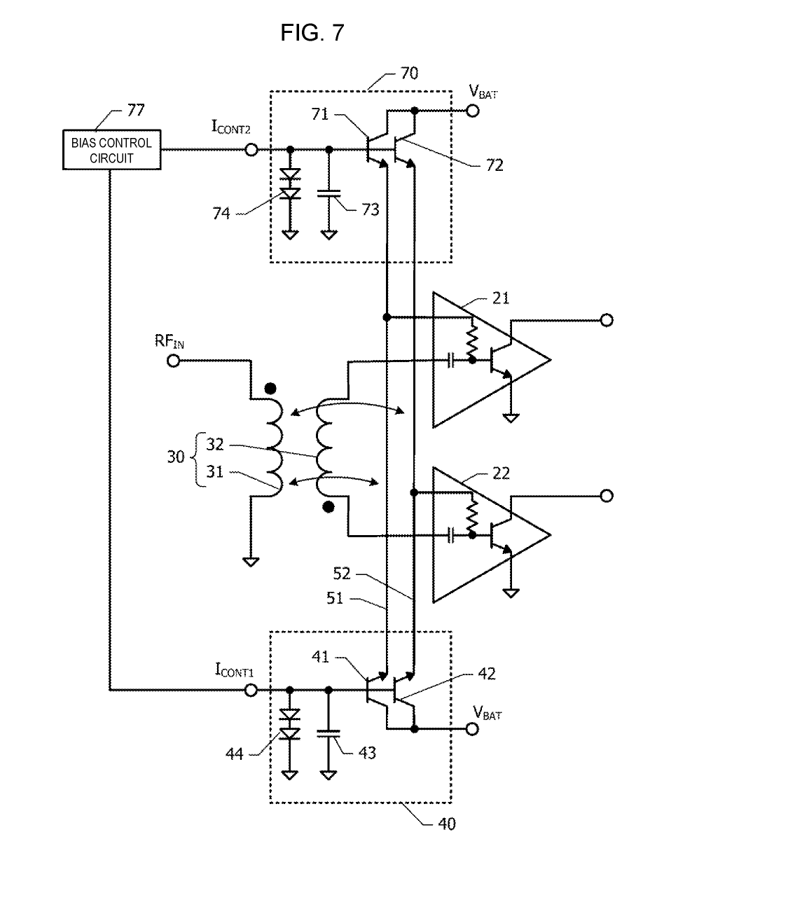

Next, a differential amplifier circuit according to a second embodiment is described with reference to FIGS. 7 to 11B. The following omits descriptions of configurations shared with the differential amplifier circuit according to the first embodiment described with reference to FIGS. 1 to 5.

FIG. 7 is an equivalent circuit diagram of the differential amplifier circuit according to the second embodiment. The differential amplifier circuit of the second embodiment includes a second bias circuit 70 in addition to the first bias circuit 40 of the differential amplifier circuit according to the first embodiment. The second bias circuit 70 has the same circuit configuration as the first bias circuit 40. The second bias circuit 70 includes a third transistor 71, a fourth transistor 72, a capacitor 73, and a diode circuit 74. The third transistor 71 and the fourth transistor 72 are connected in an emitter-follower configuration.

The second bias circuit 70 supplies a bias current to each of the first amplifier 21 and the second amplifier 22. Specifically, the collectors of the third transistor 71 and the fourth transistor 72 are connected to the bias power supply voltage V_{BAT}. The emitter of the third transistor 71 is connected to the first amplifier 21 via the first bias interconnection 51, and the emitter of the fourth transistor 72 is connected to the second amplifier 22 via the second bias interconnection 52.

A bias control circuit 77 supplies bias control currents I_{CONT1} and I_{CONT2} to the first bias circuit 40 and the second bias circuit 70, respectively. The first bias circuit 40 operates when the bias control current I_{CONT1} is supplied to the first bias circuit 40, and the first bias circuit 40 goes into a non-operating state when supply of the bias control current I_{CONT1} is stopped. Similarly, the second bias circuit 70 operates when the bias control current I_{CONT2} is supplied to the second bias circuit 70, and the second bias circuit 70 goes into a non-operating state when supply of the bias control current I_{CONT2} is stopped.

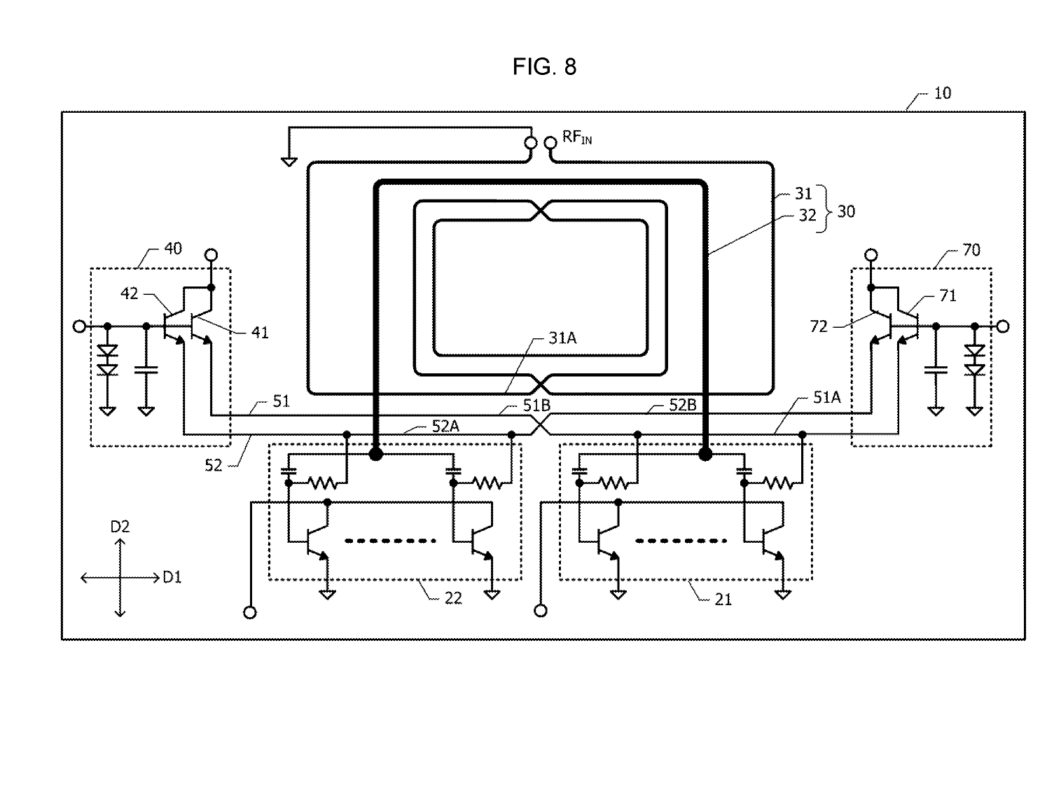

FIG. 8 is a diagram showing the layout of a plurality of components of the differential amplifier circuit according to the second embodiment. In the second embodiment, the second bias circuit 70 is formed on the semiconductor substrate 10 in addition to the first bias circuit 40. The second bias circuit 70 is disposed at a position such that the first amplifier 21 and the second amplifier 22 are sandwiched between the second bias circuit 70 and the first bias circuit 40 in the first direction D1. Thus, the second bias circuit 70 is disposed in a region at an opposite side of the first amplifier 21 from the second amplifier 22 in terms of the first direction D1.

A second middle portion 52B of the second bias interconnection 52 is disposed between the first amplifier connection portion 51A of the first bias interconnection 51 and the primary coil 31 of the input matching circuit 30 and extends in the first direction D1. The emitter of the fourth transistor 72 is connected to the second amplifier 22 via the second middle portion 52B. The first bias interconnection 51 and the second bias interconnection 52 intersect with each other between the first amplifier connection portion 51A and the first middle portion 51B and between the second amplifier connection portion 52A and the second middle portion 52B.

The second middle portion 52B of the second bias interconnection 52 is electromagnetically coupled with the primary coil 31 of the input matching circuit 30. Thus, once the second bias circuit 70 goes into operation, the gain G₂ of the second amplifier 22 increases with a rise in the output power from the differential amplifier circuit. Once the first bias circuit 40 goes into operation, the gain G₁ of the first amplifier 21 increases with a rise in the output power from the differential amplifier circuit, as in the first embodiment (FIG. 4D).

The signal source impedance and load impedance of the first amplifier 21 and the second amplifier 22 fluctuate based on frequency. Thus, in a configuration in which the gain of one of the first amplifier 21 and the second amplifier 22 increases, asymmetry of gain may be mitigated in a particular frequency band, but is not necessarily mitigated in other frequency bands.

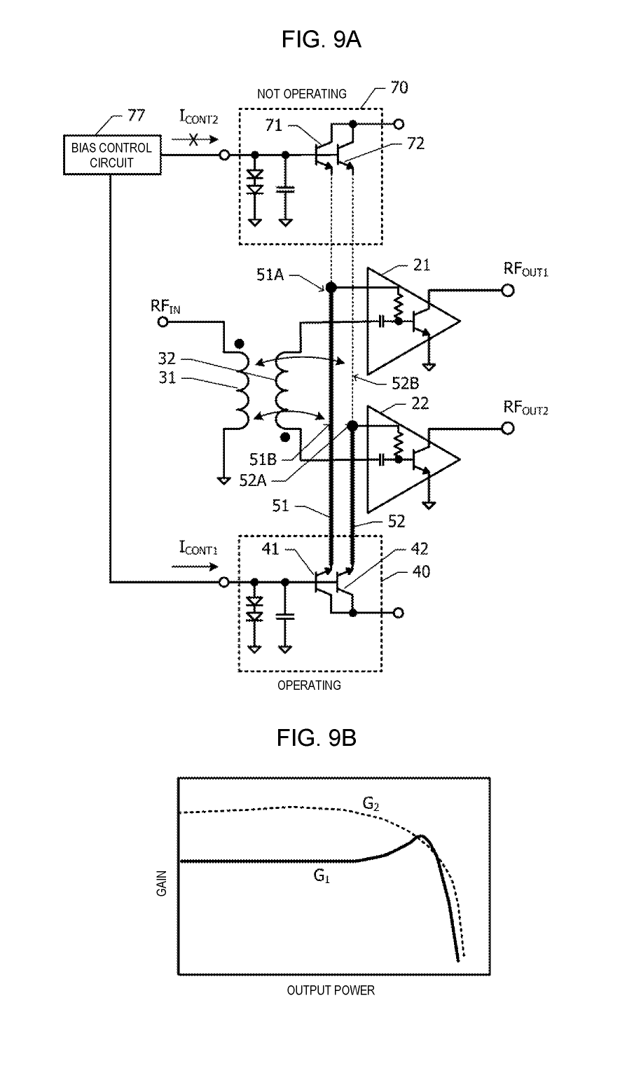

With reference to FIGS. 9A and 9B, a description is given of the operation of the differential amplifier circuit operating in a frequency range where the gain G₁ of the first amplifier 21 is smaller than the gain G₂ of the second amplifier 22 in a range where the output power is sufficiently small.

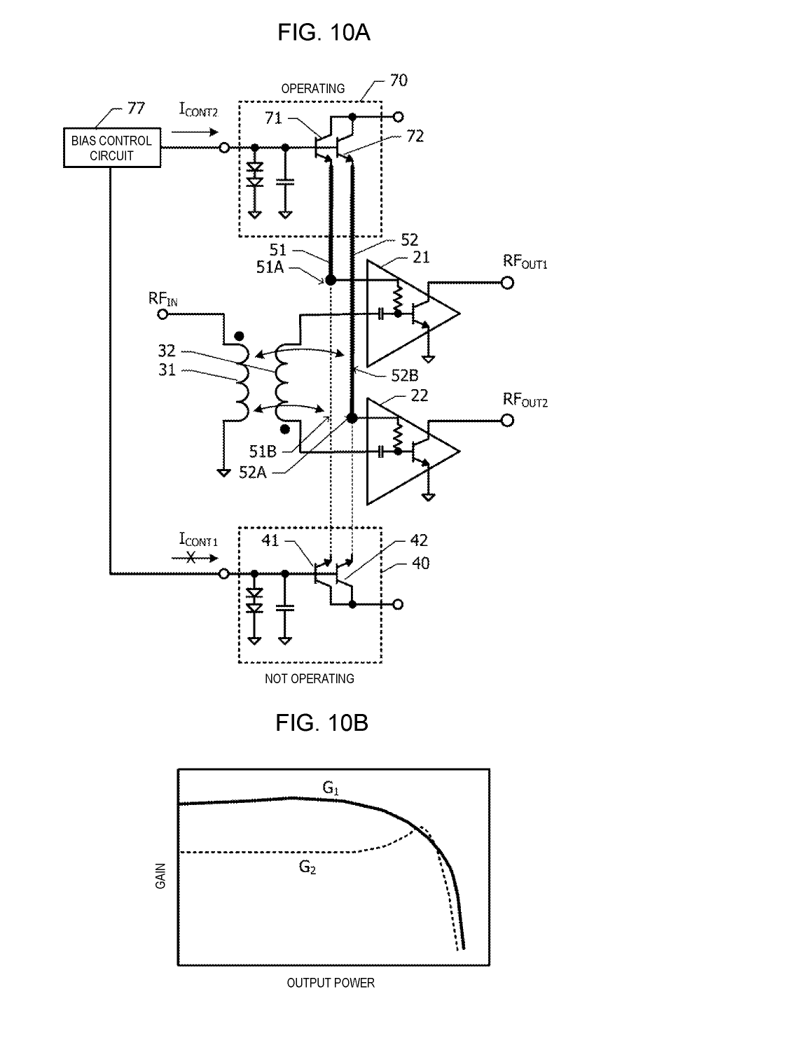

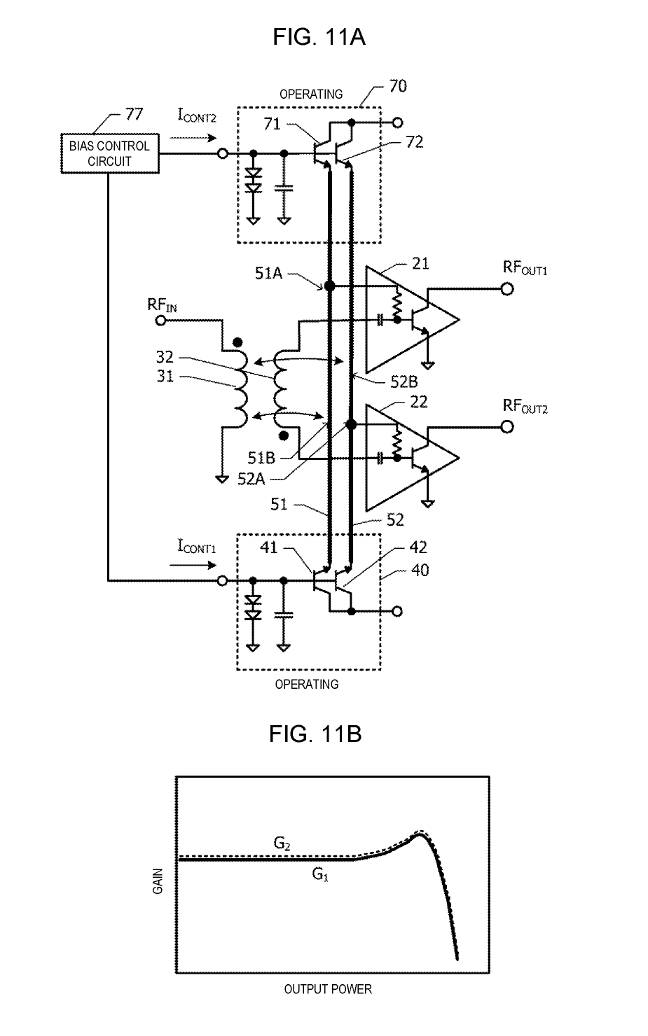

FIG. 9A is an equivalent circuit diagram illustrating the operation of the differential amplifier circuit according to the second embodiment. The bias control circuit 77 supplies the bias control current I_{CONT1} to the first bias circuit 40, and does not supply the bias control current I_{CONT2} to the second bias circuit 70. Consequently, the first bias circuit 40 operates, and the second bias circuit 70 is in a non-operating state. In FIG. 9A, the thick lines represent portions of the first bias interconnection 51 and the second bias interconnection 52 where the bias current flows, and the broken lines represent portions of the first bias interconnection 51 and the second bias interconnection 52 where the bias current does not flow. This applies also to FIGS. 10A and 11A to be described later.

Electromagnetic coupling between the first middle portion 51B of the first bias interconnection 51 and the primary coil 31 causes the emitter voltage of the first transistor 41 of the first bias circuit 40 to be deflected greatly. As a result, a notable self-bias effect is exhibited at the first amplifier 21. By contrast, as to the second bias interconnection 52, electromagnetic coupling between the second middle portion 52B and the primary coil 31 does not greatly affect the emitter voltage of the second transistor 42. Thus, the self-bias effect is less likely to be exhibited at the second amplifier 22.

FIG. 9B is a graph showing an example of a relationship between the output power and the gains G₁ and G₂ of the first amplifier 21 and the second amplifier 22. The horizontal axis represents output power, and the vertical axis represents gain. The solid line and the broken line in FIG. 9B represent the gain G₁ of the first amplifier 21 and the gain G₂ of the second amplifier 22, respectively. The gain G₁ of the first amplifier 21 is smaller than the gain G₂ of the second amplifier 22 in a range where the output power is sufficiently small. As the output power increases, the gain G₁ of the first amplifier 21 increases due to the self-bias effect. Thus, asymmetry in gain caused by an increase in output power can be mitigated.

Next, with reference to FIGS. 10A and 10B, a description is given of the operation of the differential amplifier circuit operating in a frequency range where the gain G₁ of the first amplifier 21 is larger than the gain G₂ of the second amplifier 22 in a range where the output power is sufficiently small.

FIG. 10A is an equivalent circuit diagram illustrating the operation of the differential amplifier circuit according to the second embodiment. The bias control circuit 77 supplies the bias control current I_{CONT2} to the second bias circuit 70, and does not supply the bias control current I_{CONT1} to the first bias circuit 40. Consequently, the second bias circuit 70 operates, and the first bias circuit 40 is in a non-operating state.

Electromagnetic coupling between the second middle portion 52B of the second bias interconnection 52 and the primary coil 31 causes the emitter voltage of the fourth transistor 72 of the second bias circuit 70 to be deflected greatly. As a result, a notable self-bias effect is exhibited at the second amplifier 22. By contrast, as to the first bias interconnection 51, electromagnetic coupling between the first middle portion 51B and the primary coil 31 does not greatly affect the emitter voltage of the third transistor 71. Thus, the self-bias effect is less likely to be exhibited at the first amplifier 21.

FIG. 10B is a graph showing an example of a relationship between the output power and the gains G₁ and G₂ of the first amplifier 21 and the second amplifier 22. The horizontal axis represents output power, and the vertical axis represents gain. The solid line and the broken line in FIG. 10B represent the gain G₁ of the first amplifier 21 and the gain G₂ of the second amplifier 22, respectively. The gain G₁ of the first amplifier 21 is larger than the gain G₂ of the second amplifier 22 in a range where the output power is sufficiently small. As the output power increases, the gain G₂ of the second amplifier 22 increases due to the self-bias effect. Thus, asymmetry in gain caused by an increase in output power can be mitigated.

Next, with reference to FIGS. 11A and 11B, a description is given of the operation of the differential amplifier circuit operating in a frequency range where the gain G₁ of the first amplifier 21 is almost equal to the gain G₂ of the second amplifier 22 in a range where the output power is sufficiently small.

FIG. 11A is an equivalent circuit diagram illustrating the operation of the differential amplifier circuit according to the second embodiment. The bias control circuit 77 supplies the bias control currents I_{CONT1} and I_{CONT2} to the first bias circuit 40 and the second bias circuit 70, respectively. Thus, both the first bias circuit 40 and the second bias circuit 70 operate. When the output power increases, a notable self-bias effect is exhibited at both the first amplifier 21 and the second amplifier 22.

FIG. 11B is a graph showing an example of a relationship between the output power and the gains G₁ and G₂ of the first amplifier 21 and the second amplifier 22. The horizontal axis represents output power, and the vertical axis represents gain. The solid line and the broken line in FIG. 11B represent the gain G₁ of the first amplifier 21 and the gain G₂ of the second amplifier 22, respectively. The gain G₁ of the first amplifier 21 is almost equal to the gain G₂ of the second amplifier 22 in a range where the output power is sufficiently small. As the output power increases, the gain G₁ of the first amplifier 21 and the gain G₂ of the second amplifier 22 both increase. Thus, the upper-limit value of the output power can be increased while maintaining the symmetry in gain after an increase in the output power.

### Next, an effect of the second embodiment is described

According to the second embodiment, even if the differential amplifier circuit has asymmetry such that the gain G₁ of the first amplifier 21 and the gain G₂ of the second amplifier 22 differ in magnitude depending on the operating frequency, asymmetry caused by an increase in output power can be mitigated. Thus, the differential amplifier circuit can operate in a wider frequency band.

### Third Embodiment

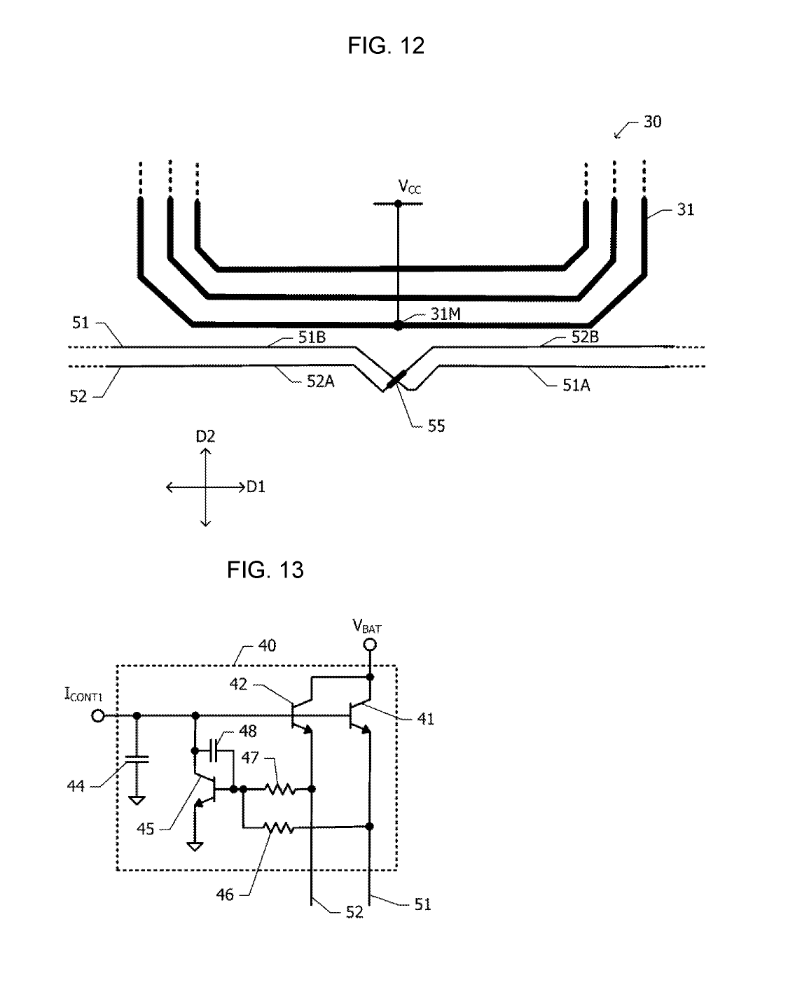

Next, a differential amplifier circuit according to a third embodiment is described with reference to FIG. 12. The following omits descriptions of configurations shared with the differential amplifier circuit according to the second embodiment described with reference to FIGS. 7 to 11B.

FIG. 12 is a schematic plan view showing the layout of the primary coil 31 of the input matching circuit 30, the first bias interconnection 51, and the second bias interconnection 52 of the differential amplifier circuit according to the third embodiment. The first bias interconnection 51 and the second bias interconnection 52 intersect with each other three-dimensionally as with the second embodiment (FIG. 8). This intersection location 55 is located between the first amplifier connection portion 51A and the first middle portion 51B of the first bias interconnection 51 and between the second amplifier connection portion 52A and the second middle portion 52B of the second bias interconnection 52.

The power supply voltage V_{CC} is applied to the midpoint 31M on the primary coil 31. The power supply voltage V_{CC} is supplied to the preceding amplifier via the primary coil 31. The midpoint 31M on the primary coil 31 and the intersection location 55 are disposed at positions almost the same in terms of the first direction D1 and at a distance from each other in terms of the second direction D2.

The intersection location 55 between the first bias interconnection 51 and the second bias interconnection 52 is disposed at a position farther from the primary coil 31 in the second direction D2 than any of the first amplifier connection portion 51A of the first bias interconnection 51 and the second amplifier connection portion 52A of the second bias interconnection 52.

The conductor pattern denoted with the relatively thick solid lines in FIG. 12 is disposed in the same first wiring layer, and the conductor pattern denoted with the relatively thin solid lines is disposed in a second wiring layer different from the first wiring layer. For example, portions of the first bias interconnection 51 and the second bias interconnection 52 except for the intersection location 55 are disposed in a wiring layer different from a wiring layer in which the primary coil 31 is disposed. Thus, the portions of the first bias interconnection 51 and the second bias interconnection 52 except for the intersection location 55 are disposed away from the primary coil 31 in the thickness direction.

The second bias interconnection 52 includes a conductor pattern for the intersection location 55 disposed in the same first wiring layer as the wiring layer in which the primary coil 31 is disposed. The conductor pattern for the intersection location 55 is not away from the primary coil 31 in the thickness direction and is therefore close to the midpoint 31M of the primary coil 31. Because the power supply voltage V_{CC} is applied to the midpoint 31M of the primary coil 31, a high voltage is generated between the midpoint 31M of the primary coil 31 and the conductor pattern for the intersection location 55.

### Next, an effect of the third embodiment is described

According to the third embodiment, the intersection location 55 is disposed at a position farther away from the midpoint 31M of the primary coil 31 in the second direction D2 than the first amplifier connection portion 51A of the first bias interconnection 51 and the second amplifier connection portion 52A of the second bias interconnection 52. This positional relationship acts to weaken the intensity of the electric field generated between the midpoint 31M and the conductor pattern for the intersection location 55. The weakened intensity of the electric field mitigates the degradation in reliability that may be caused by generation of an intense electric field.

### Fourth Embodiment

Next, a differential amplifier circuit according to a fourth embodiment is described with reference to FIG. 13. The following omits descriptions of configurations shared with the differential amplifier circuit according to the first embodiment described with reference to FIGS. 1 to 5.

FIG. 13 is an equivalent circuit diagram of the first bias circuit 40 of the differential amplifier circuit according to the fourth embodiment. In the fourth embodiment, a beta-helper bias circuit is used as the first bias circuit 40. In the first embodiment (FIG. 1), the diode circuit 44 is used to generate the base potential of the first bias circuit 40. By contrast, in the fourth embodiment, a pull-down transistor 45 is used in place of the diode circuit 44. An HBT is used as the pull-down transistor 45, and its collector is connected to the bases of the first transistor 41 and the second transistor 42.

The emitter of the pull-down transistor 45 is connected to the reference potential. The base of the pull-down transistor 45 is connected to the emitter of the first transistor 41 via a resistance element 46 and to the emitter of the second transistor 42 via a resistance element 47. Further, a capacitor 48 is connected between the base and emitter of the pull-down transistor 45.

Part of the bias control current I_{CONT1} supplied to the first bias circuit 40 is pulled down to the reference potential through the pull-down transistor 45, and the rest of the current is supplied to the bases of the first transistor 41 and the second transistor 42. The current pulled down from the bias control current I_{CONT1} fluctuates in accordance with the emitter voltages of the first transistor 41 and the second transistor 42. Thus, negative feedback acts to stabilize the emitter voltages of the first transistor 41 and the second transistor 42.

### Next, an effect of the fourth embodiment is described

According to the fourth embodiment, the emitter voltages of the first transistor 41 and the second transistor 42 are stabilized. This stabilizes the base voltages of the amplification transistor 21Q of the first amplifier 21 (FIG. 1) and the amplification transistor 22Q of the second amplifier 22 (FIG. 1). As a result, excessive decrease in gain and decrease in output can be mitigated for the amplifier where no self-bias effect is exhibited.

### Fifth Embodiment

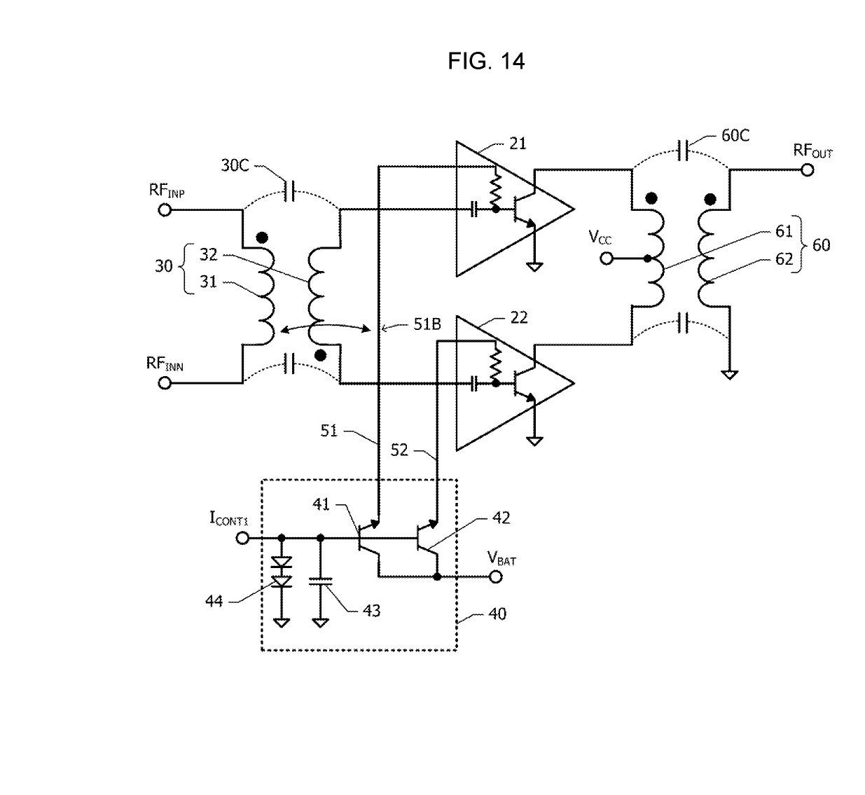

Next, a differential amplifier circuit according to a fifth embodiment is described with reference to FIG. 14. The following omits descriptions of configurations shared with the differential amplifier circuit according to the first embodiment described with reference to FIGS. 1 to 5.

FIG. 14 is an equivalent circuit diagram of the differential amplifier circuit according to the fifth embodiment. In the first embodiment (FIG. 1), a balun that converts a single-ended signal into a differential signal is used as the input matching circuit 30. By contrast, in the fifth embodiment, an input signal to the input matching circuit 30 is also a differential signal. A non-inverted signal RF_{INP} and an inverted signal RF_{INN}, which are differential signals, are inputted to the respective end portions of the primary coil 31 of the input matching circuit 30. Thus, a transformer for impedance transformation is used as the input matching circuit 30. The first middle portion 51B of the first bias interconnection 51 electromagnetically couples with the primary coil 31 of this transformer.

### Next, an effect of the fifth embodiment is described

According to the fifth embodiment, as with the first embodiment, an effect of mitigating the asymmetry between the gain G₁ of the first amplifier 21 and the gain G₂ of the second amplifier 22 caused by a rise in output power is obtained.

### Next, a differential amplifier circuit according to a modification of the fifth embodiment is described

In the fifth embodiment, a balun that converts a differential signal into a single-ended signal is used as the output matching circuit 60. As a modification of the fifth embodiment, a transformer that outputs a differential signal may be used as the output matching circuit 60. In a case where a subsequent differential amplifier circuit is connected to the active output node of the output matching circuit 60, the asymmetry in the subsequent differential amplifier circuit may cause the asymmetry between the load impedance of the first amplifier 21 and the load impedance of the second amplifier 22 in the preceding stage. According to the modification of the fifth embodiment, such asymmetry in load impedance can be mitigated.

### Sixth Embodiment

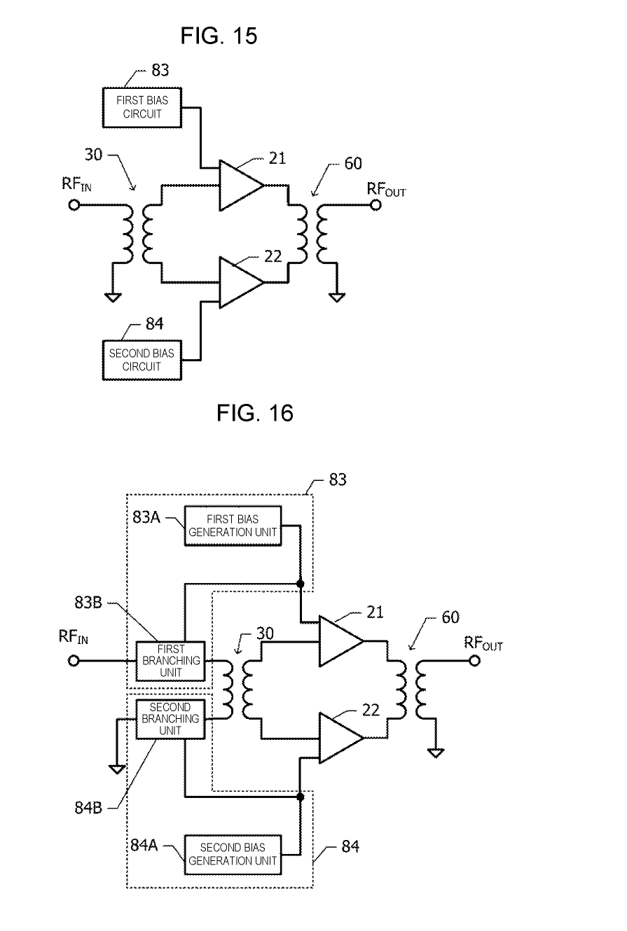

### Next, a differential amplifier circuit according to a sixth embodiment is described with reference to FIG. 15

FIG. 15 is a block diagram of the differential amplifier circuit of the sixth embodiment. The input matching circuit 30 converts the high-frequency signal RF_{IN}, which is a single-ended signal, into a differential signal. The differential signal outputted from the input matching circuit 30 is inputted to the first amplifier 21 and the second amplifier 22 forming a differential pair. The first amplifier 21 and the second amplifier 22 amplify the differential signal. The differential signal outputted from the first amplifier 21 and the second amplifier 22 is converted into a single-ended signal by the output matching circuit 60, and the high-frequency signal RF_{OUT} is outputted. A description is given of an example in which when the input power is low, the gain of the first amplifier 21 is smaller than the gain of the second amplifier 22 due to the asymmetry in signal impedance and load impedance between the first amplifier 21 and the second amplifier 22.

A first bias circuit 83 and a second bias circuit 84 supply a bias to the first amplifier 21 and the second amplifier 22, respectively. The first bias circuit 83 is configured to adjust the bias in the direction in which the gain of the first amplifier 21 increases when the power of the differential signal inputted to the first amplifier 21 and the second amplifier 22 becomes high. The second bias circuit 84 is configured to adjust the bias in the direction in which the gain of the second amplifier 22 increases when the power of the differential signal inputted to the first amplifier 21 and the second amplifier 22 becomes high, under the condition that the amount of gain increase of the second amplifier 22 is smaller than the amount of gain increase of the first amplifier 21. For example, the first bias circuit 83 and the second bias circuit 84 adjust the bias based on a bias adjustment signal obtained from various circuit elements constituting the differential amplifier circuit.

Note that the second bias circuit 84 may be configured not to increase the gain of the second amplifier 22 even if the power of the differential signal inputted to the first amplifier 21 and the second amplifier 22 becomes high.

As an example, the function of the first bias circuit 83 is implemented by, for example, the first transistor 41 and the first bias interconnection 51 electromagnetically coupled with the primary coil 31 in the first embodiment (FIG. 1). The function of the second bias circuit 84 is implemented by, for example, the second transistor 42 and the second bias interconnection 52 not electromagnetically coupled with the primary coil 31 in the first embodiment (FIG. 1).

### Next, an effect of the sixth embodiment is described

According to the sixth embodiment, as with the first embodiment, an effect of mitigating the asymmetry between the gains of the first amplifier 21 and the second amplifier 22 when the input power and the output power of the differential amplifier circuit increase is obtained.

Next, differential amplifier circuits according to various modifications of the sixth embodiment are described with reference to FIGS. 16 to 19. FIGS. 16 to 19 are block diagrams of the differential amplifier circuits according to the various modifications of the sixth embodiment. The modifications described below show example configurations of the first bias circuit 83 and the second bias circuit 84 of the sixth embodiment (FIG. 15).

In the modification shown in FIG. 16, the first bias circuit 83 includes a first bias generation unit 83A and a first branching unit 83B, and the second bias circuit 84 includes a second bias generation unit 84A and a second branching unit 84B. The first bias generation unit 83A and the second bias generation unit 84A each output a bias current.

The first branching unit 83B and the second branching unit 84B are respectively inserted into one and the other one of transmission lines on the primary coil side of the input matching circuit 30. The first branching unit 83B and the second branching unit 84B generate a bias adjustment signal based on an input signal to the input matching circuit 30. The bias adjustment signal generated by the first branching unit 83B is added to the bias current outputted from the first bias generation unit 83A, and the total current is inputted to the first amplifier 21 as a bias current. Similarly, the bias adjustment signal generated by the second branching unit 84B is added to the bias current outputted from the second bias generation unit 84A, and the total current is inputted to the second amplifier 22 as a bias current.

In this way, in the modification shown in FIG. 16, the bias adjustment signal for adjusting the bias is obtained from a high-frequency signal transmitted through the transmission line on the primary coil side of the input matching circuit 30. If the second bias circuit 84 does not have the function to adjust the bias in the direction in which the gain of the second amplifier 22 increases, the second branching unit 84B does not have to be inserted.

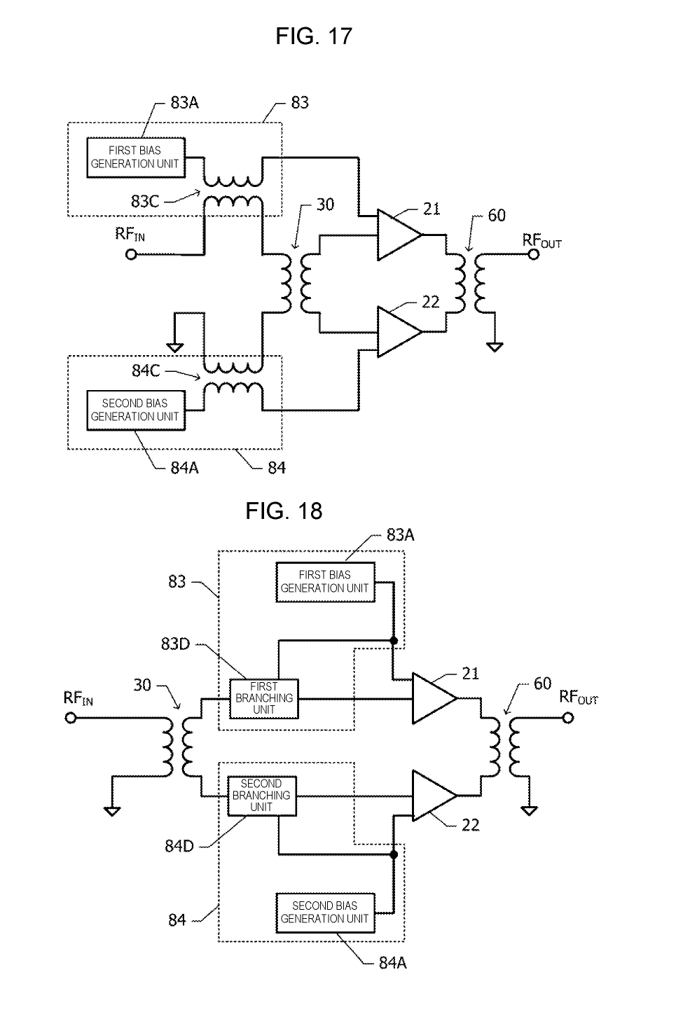

In the modification shown in FIG. 17, inductive coupling circuits 83C and 84C are used as the first branching unit 83B and the second branching unit 84B (FIG. 16). An inductive current generated based on the high-frequency signal transmitted through the transmission line on the primary coil side of the input matching circuit 30 is used as the bias adjustment signal.

Adjusting the coupling coefficients of the inductive coupling circuits 83C and 84C makes it possible to adjust the amounts of gain increase of the first amplifier 21 and the second amplifier 22.

In the modification shown in FIG. 18, a first branching unit 83D and a second branching unit 84D are respectively inserted into one and the other one of transmission lines on the secondary coil side of the input matching circuit 30. With such a configuration, a bias adjustment signal may be obtained from a high-frequency signal transmitted through the transmission line on the secondary coil side of the input matching circuit 30.

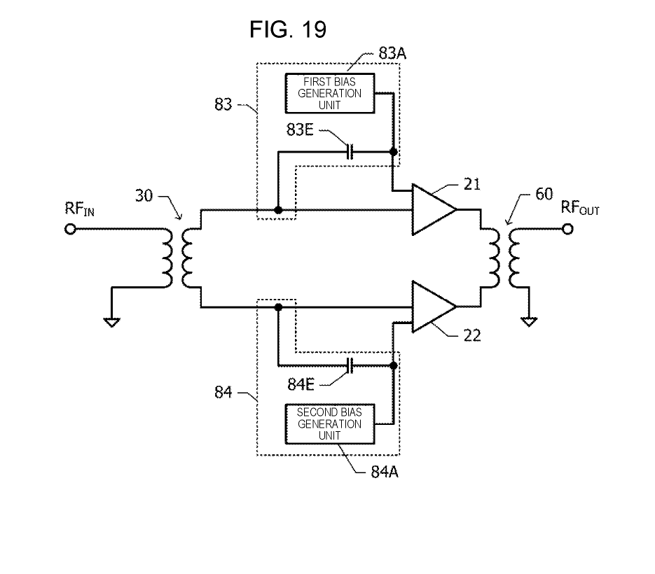

In the modification shown in FIG. 19, the first branching unit 83D (FIG. 18) is configured by a capacitor 83E. The capacitor 83E is implemented by capacitive coupling between a transmission line on the secondary coil side of the input matching circuit 30 and a bias current path from the first bias generation unit 83A to the first amplifier 21. Similarly, the second branching unit 84D (FIG. 18) is configured by a capacitor 84E. The capacitor 84E is implemented by capacitive coupling between a transmission line on the secondary coil side of the input matching circuit 30 and a bias current path from the second bias generation unit 84A to the second amplifier 22.

With such a configuration, a bias adjustment signal may be obtained from the transmission line on the secondary coil side of the input matching circuit 30 via the capacitive coupling circuit. Note that like in the modification shown in FIG. 17, inductive coupling circuits may be used as the first branching unit 83D and the second branching unit 84D in FIG. 18. Also, capacitive coupling circuits may be used as the first branching unit 83B and the second branching unit 84B of the modification shown in FIG. 16.

The embodiments described above are merely exemplary, and it goes without saying that configurations shown in different embodiments can be partially replaced or combined. Similar operational effects achieved by similar configurations in a plurality of embodiments are not repeatedly described for each embodiment. Further, the present disclosure is not limited to the embodiments described above. It should be apparent to those skilled in the art that, for example, various changes, improvements, combinations, and the like are possible.

What is claimed is:

1. A differential amplifier circuit comprising:
a first amplifier and a second amplifier configured to amplify a differential signal;
an input matching circuit comprising a primary coil and a secondary coil that are inductively coupled with each other, the secondary coil being connected at a first end to an input node of the first amplifier and at a second end to an input node of the second amplifier, the input matching circuit being configured to output a high-frequency signal inputted to the primary coil from the secondary coil;
a first bias circuit configured to supply a bias to each of the first amplifier and the second amplifier;
a first bias interconnection connecting the first bias circuit and the first amplifier, and serving as a bias supply path;
a second bias interconnection connecting the first bias circuit and the second amplifier, and serving as a bias supply path; and
a substrate on which the first amplifier, the second amplifier, the input matching circuit, the first bias circuit, the first bias interconnection, and the second bias interconnection are located,
wherein the first bias circuit comprises a first transistor and a second transistor connected in an emitter-follower configuration or in a source-follower configuration, with collectors or drains of the first transistor and the second transistor being connected to a bias power supply voltage, an emitter or a source of the first transistor being connected to the first amplifier via the first bias interconnection, and an emitter or a source of the second transistor being connected to the second amplifier via the second bias interconnection,
wherein the first amplifier and the second amplifier are arrayed in a first direction parallel to a surface of the substrate, with the first transistor and the second transistor being disposed within a region located on an opposite side of the second amplifier from the first amplifier in the first direction, and
wherein the first bias interconnection includes a first middle portion extending in the first direction and between the primary coil and a second amplifier connection portion of the second bias interconnection, the second amplifier connection portion being connected to the second amplifier, the first middle portion connecting the first transistor and a first amplifier connection portion of the first bias interconnection, the first amplifier connection portion being connected to the first amplifier.

2. The differential amplifier circuit according to claim 1,
wherein the primary coil includes a first coupling portion extending in the first direction, and
wherein the first coupling portion is between an end of the primary coil and a midpoint of the primary coil, the end of the primary coil having a same polarity as the first end of the secondary coil connected to the first amplifier.

3. The differential amplifier circuit according to claim 1, further comprising:
a second bias circuit on the substrate and configured to supply a bias to each of the first amplifier and the second amplifier,
wherein the second bias circuit comprises a third transistor and a fourth transistor connected in an emitter-follower configuration or in a source-follower configuration, with collectors or drains of the third transistor and the fourth transistor being connected to a bias power supply voltage, an emitter or a source of the third transistor being connected to the first amplifier via the first bias interconnection, and an emitter or a source of the fourth transistor being connected to the second amplifier via the second bias interconnection,
wherein the second bias interconnection includes a second middle portion between the primary coil and the first amplifier connection portion of the first bias interconnection, and extending in the first direction, the second middle portion connecting the second amplifier connection portion and the fourth transistor.

4. The differential amplifier circuit according to claim 3,
wherein the first bias interconnection and the second bias interconnection intersect with each other three-dimensionally between the first amplifier connection portion and the first middle portion of the first bias interconnection, and between the second amplifier connection portion and the second middle portion of the second bias interconnection, and
wherein a location where the first bias interconnection and the second bias interconnection intersect with each other three-dimensionally is farther from the primary coil than any of the first amplifier connection portion of the first bias interconnection and the second amplifier connection portion of the second bias interconnection are in a direction orthogonal to the first direction.

5. The differential amplifier circuit according to claim 1, wherein the first bias circuit comprises:
a pull-down transistor whose collector is connected to bases or gates of the first transistor and the second transistor and whose emitter is connected to a reference potential;
a first resistance element connected between the emitter or the source of the first transistor and a base of the pull-down transistor; and
a second resistance element connected between the emitter or the source of the second transistor and the base of the pull-down transistor.

6. A differential amplifier circuit comprising:
a first amplifier and a second amplifier configured to amplify a differential signal;
an input matching circuit comprising a primary coil and a secondary coil that are inductively coupled with each other, the secondary coil being connected at a first end to an input node of the first amplifier and at a second end to an input node of the second amplifier, the input matching circuit being configured to output a high-frequency signal inputted to the primary coil from the secondary coil;
a first bias circuit configured to supply a bias to the first amplifier; and
a second bias circuit configured to supply a bias to the second amplifier,
wherein the first bias circuit is configured to adjust the bias in a direction in which a gain of the first amplifier increases upon an increase in power of a differential signal inputted to the first amplifier and the second amplifier, and
wherein the second bias circuit is configured to, upon an increase in power of the differential signal inputted to the first amplifier and the second amplifier, either not increase a gain of the second amplifier or adjust the bias in a direction in which the gain of the second amplifier increases under a condition that an amount of gain increase of the second amplifier is smaller than an amount of gain increase of the first amplifier.

7. The differential amplifier circuit according to claim 6, wherein the first bias circuit is configured to change the bias based on a bias adjustment signal obtained from a high-frequency signal transmitted through a transmission line on one of the primary coil side and the secondary coil side.
